(19) United States
(12) Patent Application Publication
(10) Pub. No.: US 2003/0011045 A1
(43) Pub. Date: Jan. 16, 2003

(54) Compact layout for a semiconductor device

(75) Inventors: Ali Kleel, Stanford, CA (US); Mehdi F. Soltan, Stanford, CA (US); Ali Rajaei, Sunnyvale, CA (US); Hamid R. Rategh, Stanford, CA (US)

Correspondence Address: Pillsbury Winthrop LLP, Intellectual Property Group, 1600 Tysons Boulevard, McLean, VA, 22102, US

(73) Assignee: Tavanza, Inc., Santa Clara, CA

(21) Appl. No.: 09/903,303

(22) Filed: Jul. 10, 2001

(51) Int. Cl. H01L 31/0328; H01L 31/072; H01L 29/70

(52) U.S. Cl. 257/587; 257/197; 257/571; 257/573; 257/584; 257/586

(57) ABSTRACT

A semiconductor device includes a semiconductor substrate, an electrode disposed on an upper surface of the substrate, and a transistor element disposed on the upper surface of the substrate. The transistor element continuously surrounds the electrode and includes a plurality of contacts that are electrically connected to the electrode. Additionally, the transistor element compactly surrounds the electrode with a threshold distance.

### BACKGROUND OF THE INVENTION

1. Field of Invention

The present invention relates to semiconductor devices and more particularly to a compact layout for a semiconductor device.

2. Description of Related Art

Typically in the design of a power amplifier, a number of transistor elements are arranged in rows and columns and then connected to provide a large equivalent power device. For example, FIG. 11 shows a conventional layout design for a semiconductor device 132 where a number of BJTs (Bipolar Junction Transistors) 134 are arranged in rows on the upper surface of a semiconductor substrate. Each BJT 134 includes an emitter contact 136, a base contact 138, and a collector contact 140. The emitter contacts 136 are connected by metal 142 to an electrode 144 that lies between the rows of BJTs 134, and the electrode 144 lies above vias 146 that provide an electrical connection to ground. The use of vias for electrical connections is well known in the art of semiconductor devices. (“Semiconductor Device Including Via Hole and Isolating Circumferential Member”, U.S. Pat. No. 5, 917, 209) FIG. 12 shows a cross section of the semiconductor substrate through one of the vias 146. The via 146 is defined by a via inner wall 148 in the substrate 150. The upper surface electrode 144 is electrically connected to a lower surface electrode 152 by means of the via inner wall 148, and the lower surface electrode 152 is electrically connected to a ground plane 154. Then each BJT emitter is electrically connected to the ground plane 154.

For the design shown in FIG. 11 to function as a single power amplifier, the bases and the collectors must also be electrically connected. FIGS. 13A, 13B, and 13C illustrate three ways that these connections can be made for the emitters, bases and electrodes in an amplifier design. When all emitter contacts for example are connected to an upper electrode as shown in FIG. 11, then a via can be used to make an electrical connection to a lower electrode as shown in FIG. 12. Similarly FIG. 13A shows a via 154 defined by a via inner 156 wall that connects an upper electrode 158 on a semiconductor substrate 160 with a lower electrode 162. Alternatively in the above example where the emitter contacts are connected to an upper electrode, a connection to a lower electrode can be made by a wire or metal layer. In FIG. 13B an upper electrode 164 on a semiconductor substrate 166 is connected to a lower electrode 168 by means of a wire 170 that is separated from the substrate 166 by an insulator 170.

In FIGS. 13A and 13B, the lower electrode can be driven by a single voltage source. In designs without electrodes, wires from a common voltage source can be connected to the connectors that are being driven together. FIG. 13C shows a tree-structure design for inputs to the collectors in a row of eight BJTs 174 on a semiconductor substrate surface 176. A wire 178 with a tree structure connects a collector feed 180 to collector contacts 182. Since the wire path-length from the collector feed 180 to each BJT 174 is the same, difficulties associated with different path-lengths may be avoided. For example, different path-lengths may lead to differences in DC drops, in inductances, and in heat conduction in the elements of the power amplifier.

However, even when differences between elements of a power amplifier are minimized, layout and device geometries may seriously affect the maximum achievable performance of the amplifier. For example, the inductance in the paths from emitters to the ground plane may substantially affect performance of an amplifier, whether these paths are uniform or not. Additionally these paths also affect the quality of heat conduction in the device. Moreover, although examples presented here employ BJTs, similar considerations apply for designs involving other transistor elements such as FETs (Field Effect Transistors).

### SUMMARY OF THE INVENTION

Accordingly, it is an object of this invention to provide a semiconductor device that efficiently uses space on the surface of the substrate to incorporate transistors in the design.

It is a further object to provide a semiconductor device with reduced inductance.

It is a further object to provide a semiconductor device with improved heat conduction.

It is a further object to provide a semiconductor device with reduced DC drop.

The above and related objects of the present invention, taken alone or in combination, are realized by a semiconductor device that includes a semiconductor substrate, an electrode disposed on an upper surface of the substrate, and a transistor element disposed on the upper surface of the substrate. The transistor element continuously surrounds the electrode and includes a plurality of contacts that are electrically connected to the electrode. Additionally, the transistor element compactly surrounds the electrode with a threshold distance. In a specifically preferred embodiment, a threshold distance of 300 microns (or less) may be used.

The semiconductor substrate may include a via inner wall that defines a via so that the via inner wall electrically connects the electrode with a second electrode disposed on a lower surface of the substrate. Alternatively the electrode may be connected to second electrode by a metal connection.

Above the electrode an additional electrode may be disposed with an insulating layer in between. In this way the present invention enables the electrode space to be used for connections to two sets of contacts to the transistor elements. For example, the first electrode may be connected to another electrode through a via, and the second electrode may be connected to another electrode through a metal connection.

The transistor element may include additional connectors that are connected to a feed that has a tree-structure for balancing a feed signal.

The planar shape of the electrode may have an arbitrary shape. In specifically preferred embodiments, the electrode is shaped as a circle or as a polygon, and the continuous transistor element has a similar shape.

Alternatively the continuous transistor element may be replaced by a set of transistor elements, where this set compactly surrounds the electrode in a discrete sense with a threshold distance and a threshold angular value. In a specifically preferred embodiment, a threshold distance of 300 microns (or less) and a threshold angular value of 180 degrees (or more) may be used.

In this way the present invention advantageously enables an efficient use of space in the layout for semiconductor device. By minimizing and balancing path-lengths in the device, the present invention desirably reduces inductances and enhances heat conduction in the system.

### BRIEF DESCRIPTION OF THE DRAWINGS

These and other objects and advantages of the invention will become more apparent and more readily appreciated from the following detailed description of the presently preferred exemplary embodiments of the invention taken in conjunction with the accompanying drawings, where:

FIG. 1 is a top view of an embodiment of the present invention;

FIG. 2 is a segmented view associated with the embodiment shown in FIG. 1;

FIG. 3 is a cross-sectional view associated with the embodiment shown in FIG. 1;

FIG. 4 is a top view of another embodiment of the present invention;

FIG. 5 is a top view of another embodiment of the present inveniton;

FIG. 6 is a top view of an element from the embodiment shown in FIG. 5;

FIG. 7 is a cross-sectional view associated with the embodiment shown in FIG. 6;

FIG. 8 is a top view of another embodiment of the present invention related to the embodiment shown in FIG. 1;

FIG. 9 is a top view of another embodiment of the present invention;

FIG. 10 is a cross-sectional view associated with the embodiment shown in FIG. 9;

FIG. 11 is a conventional layout design for a semiconductor device;

FIG. 12 is a cross-sectional view associated with the device shown in FIG. 11;

FIGS. 13A, 13B, and 13D are views that show conventional electrical contacts for semiconductor devices;

FIGS. 14A and 14B illustrate a continuous transistor element that “compactly surrounds” an electrode; and

FIGS. 15A and 15B illustrate a set of discrete transistor elements, where the set “compactly surrounds” an electrode.

### DETAILED DESCRIPTION OF EXEMPLARY EMBODIMENTS

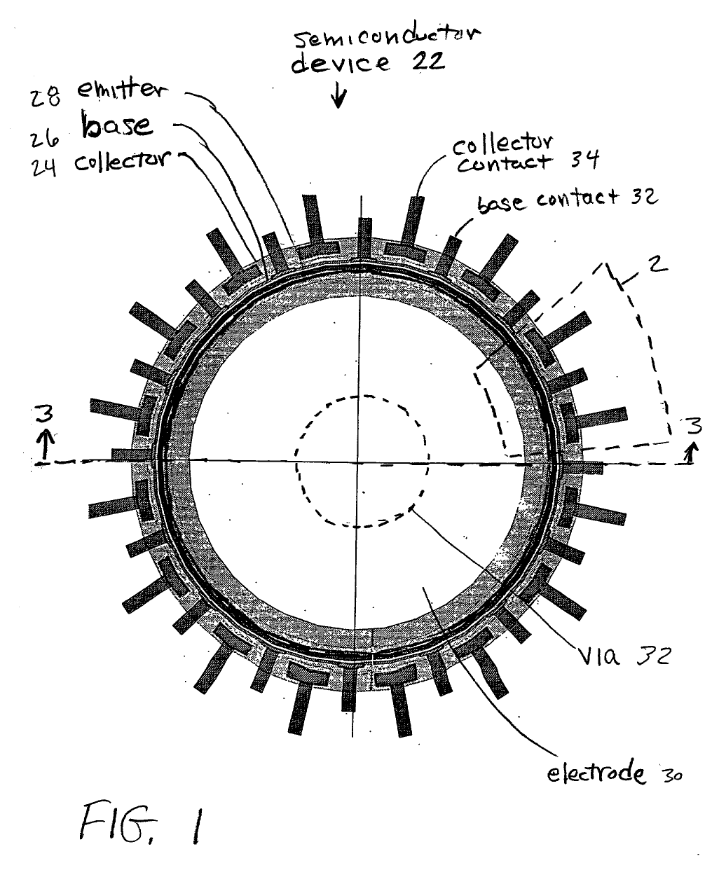

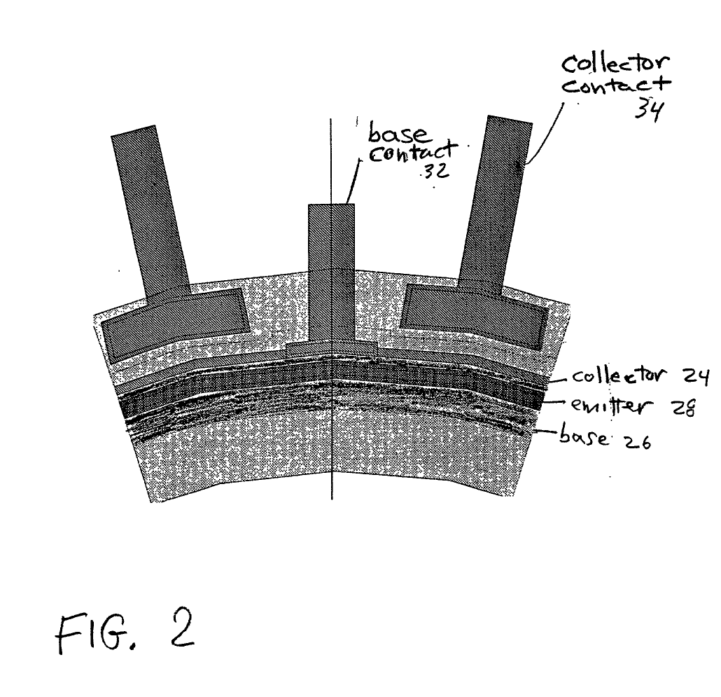

A preferred embodiment of the present invention is shown in FIG. 1. FIG. 1 shows a top view of a GaAs semiconductor device 22 with a circular layout. On a substrate upper surface, a continuous transistor element surrounds a circular layout and includes transistor layers for a collector 24, a base 26 and an emitter 28. An electrode 30 lies above a via 32 in the substrate. A section of the device is shown in FIG. 2. Base contacts 32 connect to the base 26, and collector contacts 34 connect to the collector 24. Although not shown in FIGS. 1 and 2, a metal connection joins the emitter 28 and the electrode 30.

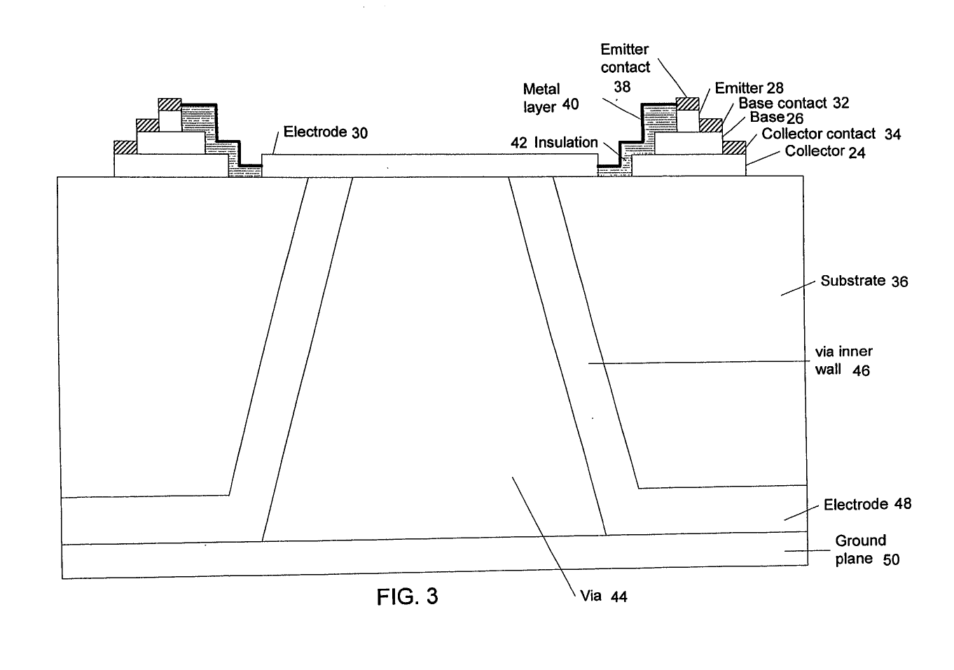

FIG. 3 shows a cross-sectional view of the device. The collector 24 is disposed on the upper surface of the substrate 36 in the shape of a mesa. Similarly the base 26 is disposed in the shape of a mesa on top of the collector 24, and the emitter 28 is disposed in the shape of a mesa on top of the base 26. In addition to the collector contacts 34 and the base contacts 32, FIG. 3 shows emitter contacts 38 that are connected by a metal layer 40 to the electrode 30. An insulation layer 42 separates this metal layer 40 from the base 26 and the collector 24. A via 44 is defined by a via inner wall 46 in the substrate 36. The via inner wall 46 makes an electrical connection between the upper electrode 30 and a lower electrode 48, which is in contact with a ground plane 50, thereby completing an electrical connection between the emitter mesa 28 and the ground plane 50.

The circular device advantageously places transistor layers (i.e., emitter 28, base 26, and collector 24) about a circular upper electrode 30 that connects to the ground plane 50 by means of the via 44. This design is desirably symmetric and desirably allows full use of the substrate surface near the upper electrode 30, thereby enabling a compact arrangement of transistor elements for a power amplifier.

By minimizing the path-length from the emitter to ground, the corresponding inductance is minimized as well as the DC drop, thereby allowing higher gains and efficiencies. Furthermore, the proximity of the active devices (i.e., the transistor layers) to the upper electrode 30 and to the via 44, desirably enables improved heat dissipation. Due to better and more balanced heat conduction, problems related to local hot nodes in the device 22 can be minimized, thereby increasing the reliability of the device 22 and also reducing the chances of local thermal runaway associated with bipolar devices.

Thus, the present invention enables a compact arrangement of transistor layers with reduced DC drop, reduced electrical inductance and improved heat conductance as compared with conventional devices. As a result, power density to a die is desirably increased so that more power can be achieved for a given die area. Although the discussion here has focussed on the emitter contacts, the symmetry of the device may also be exploited for making electrical connections to the base contacts and the collector contacts as discussed below. As the term is used here, an electrode may be any conducting surface (e.g., a metallic surface) including a pad, a metallic plane, or a ground plane.

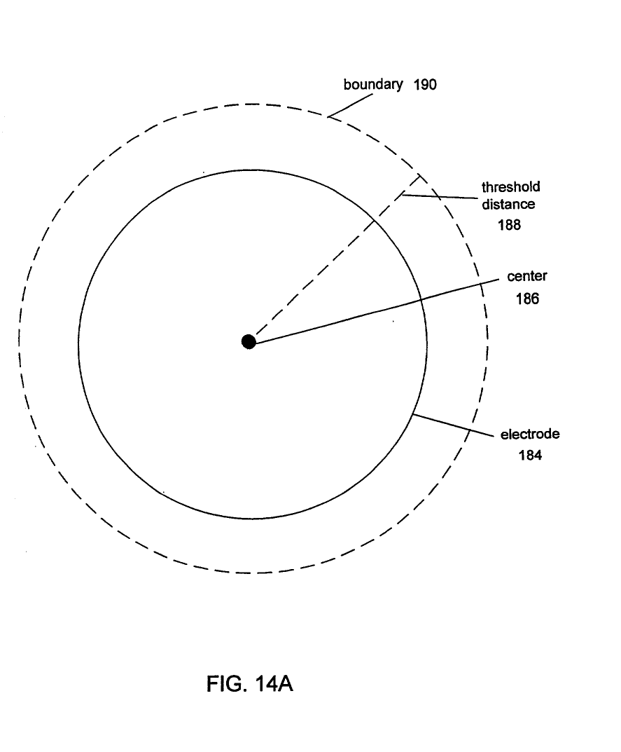

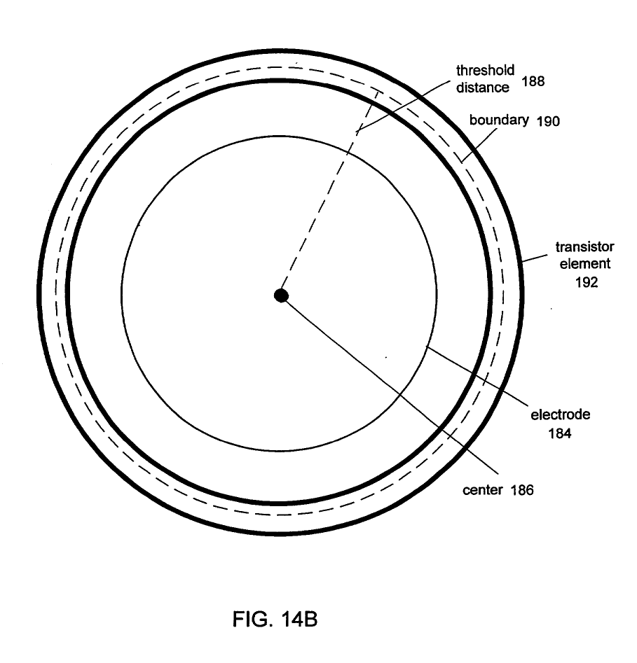

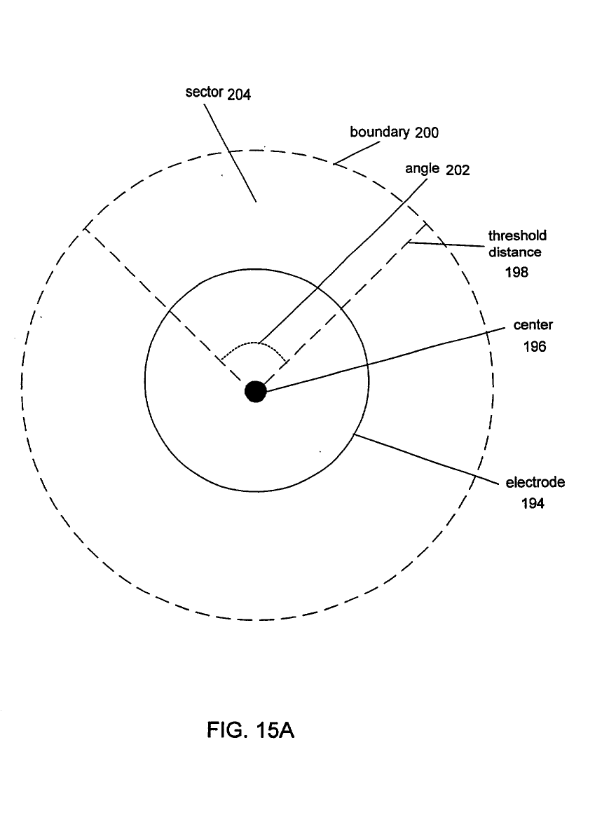

FIGS. 14A and 14B illustrate the compact arrangement of a continuous transistor element as in the embodiment of FIG. 1. In FIG. 14A, an electrode 184 has a center 186 from which a radial threshold distance 188 is measured to determine a boundary 190. This boundary 190 characterizes the radial distance within which a portion of the transistor element (e.g., a portion of the emitter contacts) must lie for a compact layout as illustrated in FIG. 1. In FIG. 14B a circular transistor element 192 has been added to represent the emitter, base and electrode layers in FIG. 1. The transistor element 192 compactly surrounds the electrode since each radial line from the center to the boundary intersects the transistor element 192. In general, the threshold distance 188 is chosen so that the path-lengths from transistor connectors to the electrode 184 is minimized or substantially limited. For example, in a specifically preferred embodiment, a threshold distance of 300 microns may be used.

For the definition above, the center 186 may be any reference point rather than the geometric center of the electrode 184. For example, in the case where the electrode 184 lies above a via, the center of the via may be used.

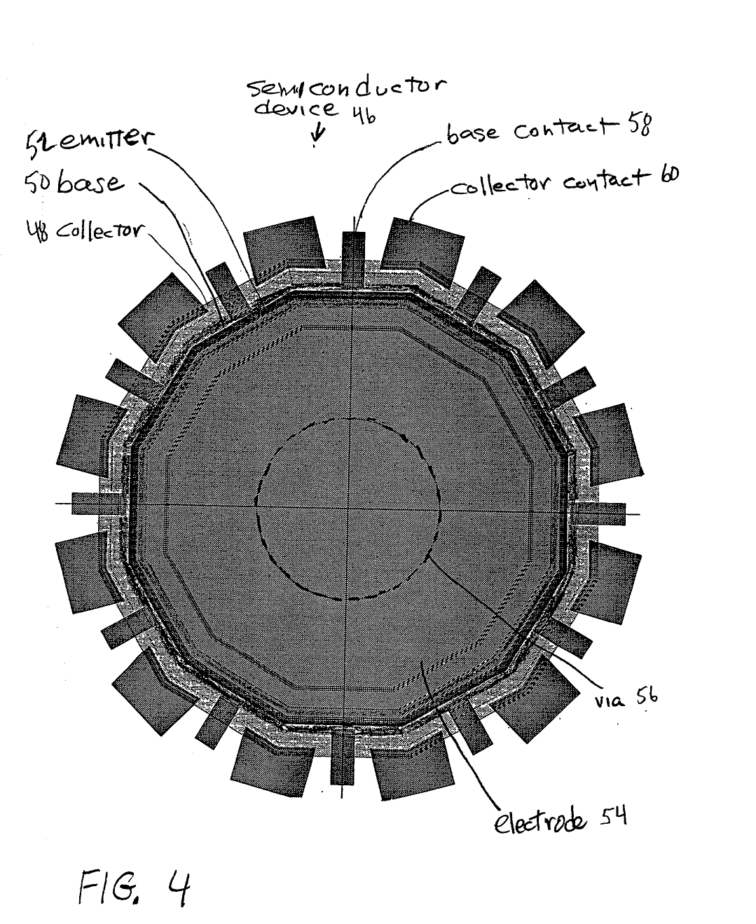

In some contexts, a layout with linear edges and corners may be preferable, for example, because of constraints in the fabrication process. FIG. 4 shows a top view of a semiconductor device 46 with a polygonal layout on a substrate upper surface. As in the circular device, semiconductor layers for a collector 48, a base 50 and an emitter 52 surround a polygonal electrode 54 on a substrate upper surface, and an electrode 54 lies above a via 56 in the substrate. FIG. 4 also shows base contacts 58 connected to the base 50, and collector contacts 60 connected to the collector 48.

In some operational settings, it is not possible to employ a device that continuously surrounds and fully encloses a via. For example, circular mesa-like (or donut-like) transistor elements as in the device shown in FIGS. 1-3 may not be possible because of constraints in the fabrication process. In this case, a continuous transistor element may be replaced by a set of discrete transistor elements.

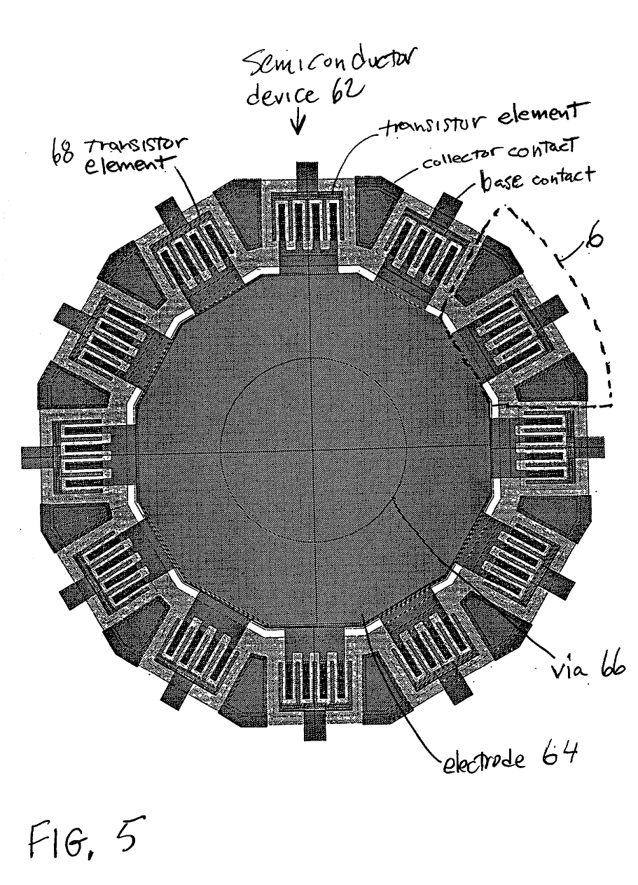

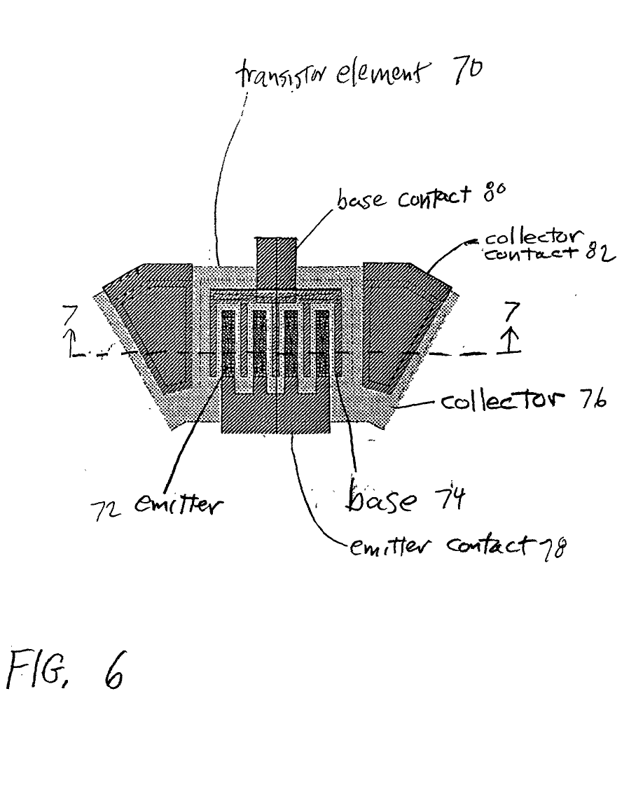

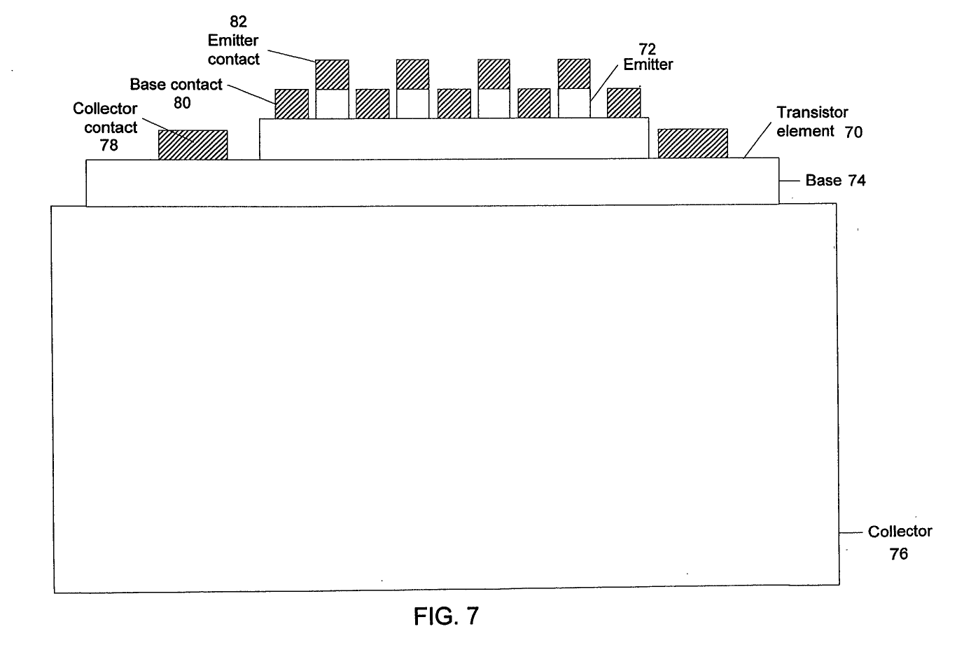

FIG. 5 shows a top view of a preferred embodiment of semiconductor device 62 with a polygonal layout on a substrate upper surface. A polygonal electrode 64 lies above a via 66 in the substrate, and transistor elements 68 are arranged about the electrode 64. A detail of a transistor element 70 is shown in FIG. 6 with a cross-sectional view shown in FIG. 7. In FIGS. 6-7 the transistor element 70 includes an emitter 72, a base 74, and a collector 76 together with an emitter contact 78, a base contact 80, and a collector contact 82. As illustrated in these figures, the base contact 80 is interdigitated with the emitter mesa 72.

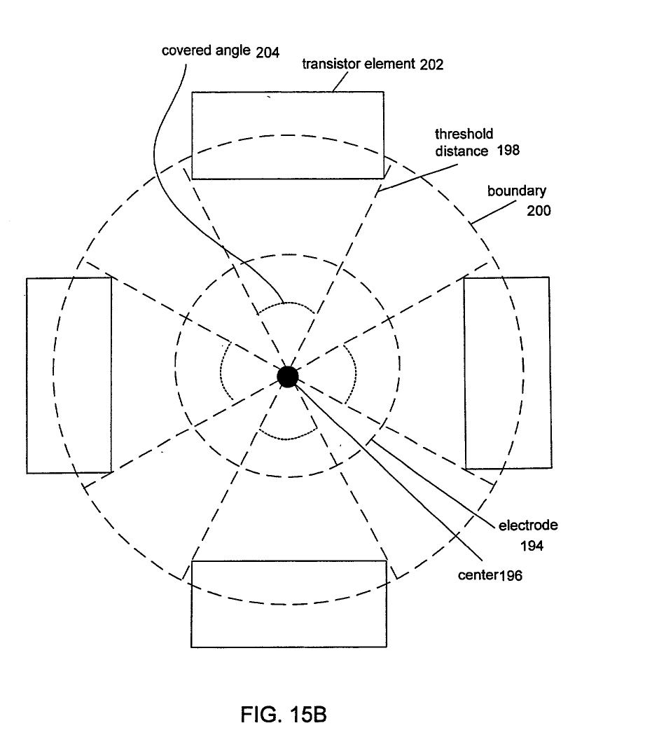

FIGS. 15A-15B illustrate an extension of the above definition for “compactly surrounds” for the case where discrete transistor elements are used as compared with the continuous transistor elements for emitter base and collector in the embodiment shown in FIGS. 1-3. In FIG. 15A an electrode 194 has a center 196 from which a radial threshold distance 198 (e.g., 300 microns) is measured to determine a boundary 200. As in FIG. 14A, this boundary characterizes the radial distance within which a transistor element must lie for a compact layout. However, for the case of a discrete transistor element, only an angular portion of the center may be “compactly surrounded” as described above for a single element. As illustrated in FIG. 15A, a transistor element compactly covers an angle 202 provided each radial line from the center 196 to the boundary 200 within the corresponding sector 204 intersects the transistor element. Then the definition of “compactly surrounds” may be extended as follows for a set of transistor elements where the set includes at least one transistor element. A set of transistor elements compactly surrounds an electrode when the sum of the covered angles corresponding to the elements is at least a threshold angular value. For example, FIG. 15B shows four elements 202 with four corresponding covered angles 204. These elements 202 compactly surround the electrode 194 provided the sum of these angles 204 is greater than some threshold angular value. For example, in a specifically preferred embodiment, a threshold angular value of 180 degrees may be used.

Similarly as in the definition based on FIGS. 14A-14B, the center 196 may be any reference point (e.g., the center of a via) rather than the geometric center of the electrode 194.

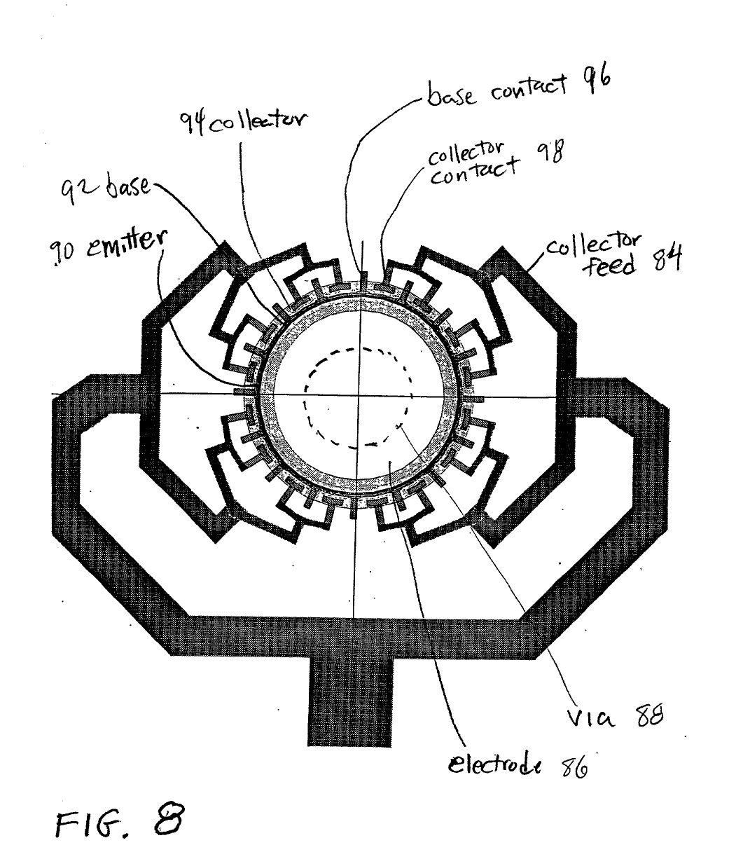

The present invention enables the efficient operation of devices discussed above by designs that exploit the geometry of the layout. For example, for the device shown in FIGS. 1-3, the emitter is electrically connected to the ground plane by means of the via. FIG. 8 shows an embodiment of a collector feed 84 with a tree structure that exploits the symmetry of the design. Similarly as in the device 22 shown in FIGS. 1-3, the embodiment of FIG. 8 includes a circular electrode 86 above a via 88. A circular transistor element includes an emitter 90, a base 92, and a collector 94. FIG. 8 also shows bases contacts 96 and collector contacts 98, which are connected to the collector feed 84. Since the emitter contacts (not shown) and the base contacts 96 are at different vertical levels as shown in FIG. 3, a base feed that has a similar tree structure may be added to the design to complete the electrical connections for the emitter 90, base 92 and collector 94.

The design shown in FIG. 8 desirably balances the delays and losses (e.g., DC drops) in the signal paths in order to minimize the uncorrelated or multi-amplitude summation of the RF signals of the base and collector since these effects can cause gain and efficiency loss. The layout shown in FIG. 8 illustrates a circular distribution network that desirably balances those delays and losses in the collector signal.

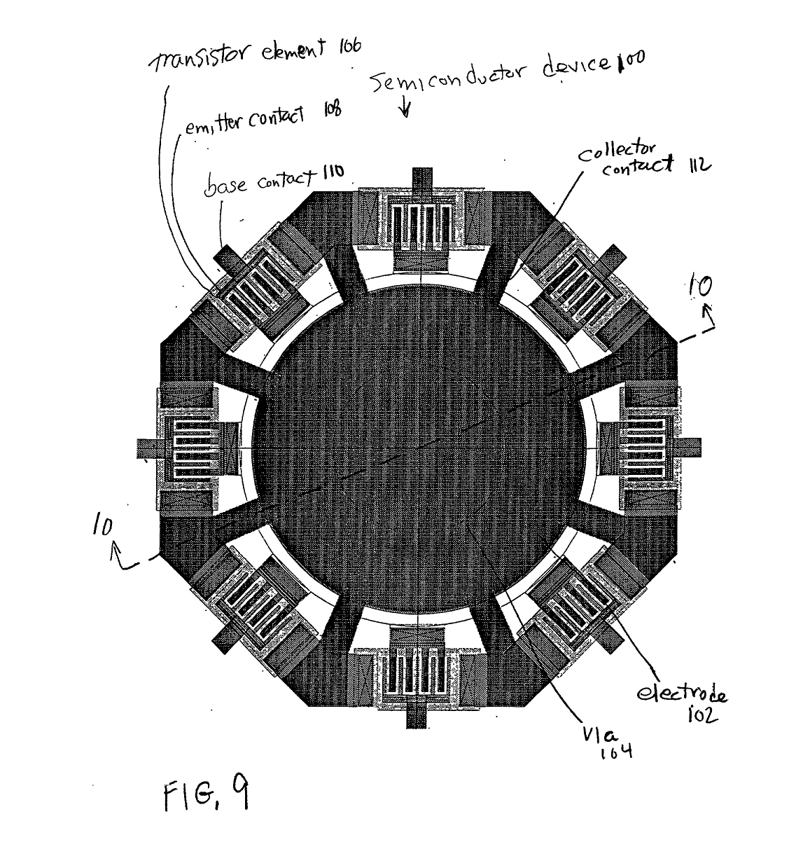

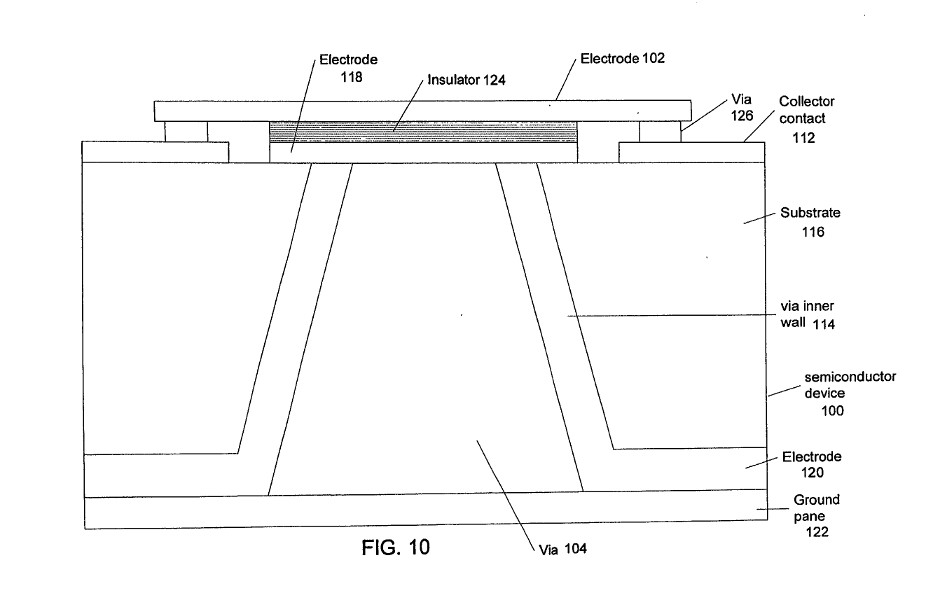

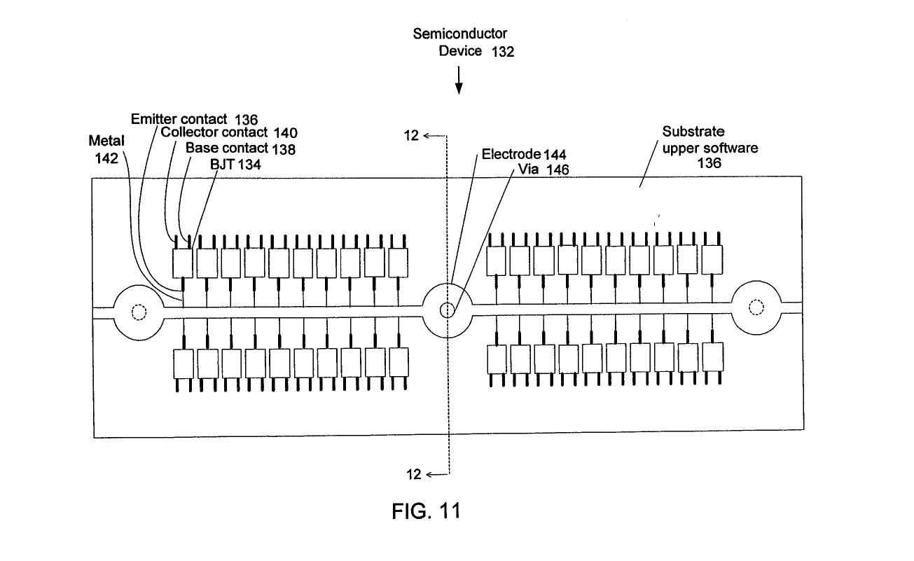

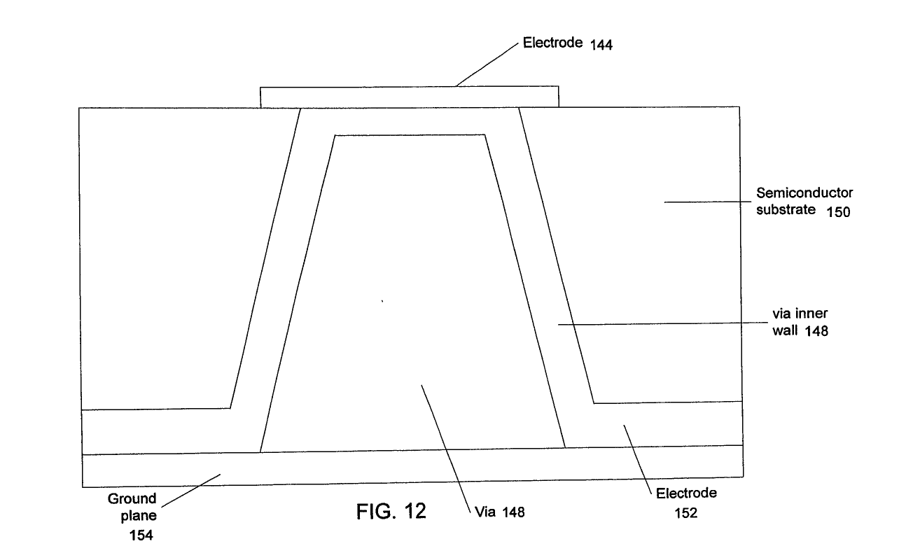

Alternatively, an additional electrode may be added to the upper surface of the substrate in order to complete the electrical connections. For example, FIG. 9 shows an embodiment that is similar to the embodiment shown in FIG. 5. FIG. 9 shows a top view of a semiconductor device 100 with a polygonal layout on a substrate upper surface. A polygonal electrode 102 lies above a via 104 in the substrate, and transistor elements 106 are arranged about the electrode 102. FIG. 9 shows emitter contacts 108, base contacts 110 and collector contacts 112. A cross-sectional view of the device 100 is shown in FIG. 10. Similarly as in FIG. 3, the via 104, defined by a via inner wall 114 in the substrate 116, makes an electrical connection from a first upper electrode 118 on the surface of the substrate 116 to a lower electrode 120 that is connected to a ground plane 122. Although not shown in FIGS. 9-10, the first upper electrode 118 is connected to the emitters as in the device shown in FIGS. 1-3.

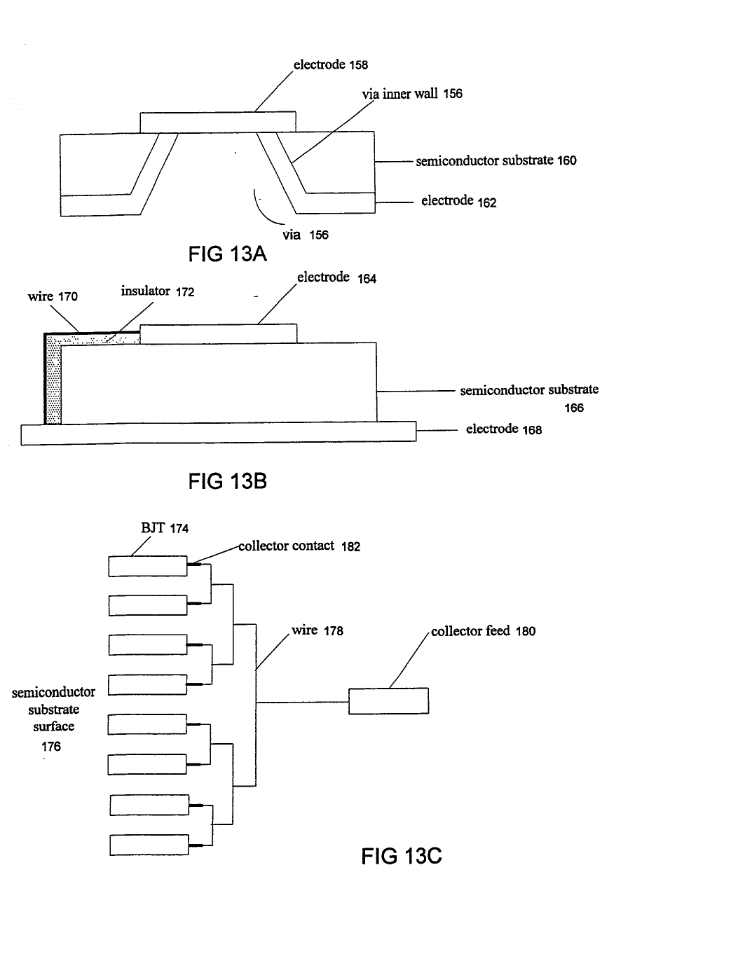

A second upper electrode 102 (i.e., as shown in FIG. 9) is separated from the first upper electrode 118 by an insulator 124, and a via 126 makes an electrical connection between the collector contacts 112 and the second upper electrode 102. Then, analogously to the connection illustrated in FIG. 13B, a wire connection (not shown) can be used to connect the second upper electrode 102 to a collector feed. The embodiment shown in FIGS. 9-10 desirably utilizes the same space on the surface of the substrate for the collector electrode and the emitter electrode while keeping these electrodes isolated electrically. As shown in FIG. 10, the second upper electrode 102 is physically and electrically isolated from the first upper electrode 118, which is grounded through the via 104. In this way the present invention effectively uses an equivalent area of one electrode for both connecting the collector contacts to a package (e.g., through wires as is FIG. 13B) and connecting the emitter contacts to a ground plane (e.g., through a via as in FIG. 13A).

Additionally, a base feed with a tree-structure geometry as shown in FIG. 8 can be added to the device to complete the electrical connections to the base connectors. As noted above, this type of feed connection may be advantageous in some application where balancing delay and loss is critical.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A semiconductor device, comprising:
a semiconductor substrate;
an electrode disposed on an upper surface of the substrate; and
a transistor element disposed on the upper surface of the substrate, the transistor element continuously surrounding the electrode, and the transistor element including a plurality of contacts that are electrically connected to the electrode, wherein the transistor element compactly surrounds the electrode with a threshold distance.

2. A semiconductor device as claimed in claim 1, wherein
the semiconductor substrate includes a via inner wall that defines a via, and
the via inner wall electrically connects the electrode with a second electrode disposed on a lower surface of the substrate.

3. A semiconductor device as claimed in claim 2, wherein the threshold distance is not more than 300 microns.

4. A semiconductor device as claimed in claim 3, further comprising:
a feed having a tree-structure for balancing a feed signal, the semiconductor element having a plurality of contacts that are electrically connected to the feed.

5. A semiconductor device as claimed in claim 4, further comprising:
a second feed having a tree-structure for balancing a feed signal, the semiconductor element having a plurality of contacts that are electrically connected to the second feed.

6. A semiconductor device as claimed in claim 2, further comprising
an insulating layer disposed on the electrode;
a third electrode disposed on the insulating layer, the transistor element including a plurality of contacts that are electrically connected to the second electrode; and
a metal connection that electrically connects the second electrode to a third electrode.

7. A semiconductor device as claimed in claim 6, wherein the threshold distance is not more than 300 microns.

8. A semiconductor device as claimed in claim 7, further comprising:
a feed having a tree-structure for balancing a feed signal, the semiconductor element having a plurality of contacts that are electrically connected to the feed.

9. A semiconductor device as claimed in claim 1, wherein a metal connection electrically connects the electrode to a second electrode.

10. A semiconductor device as claimed in claim 9, wherein the threshold distance is not more than 300 microns.

11. A semiconductor device as claimed in claim 10, further comprising:
a feed having a tree-structure for balancing a feed signal, the semiconductor element having a plurality of contacts that are electrically connected to the feed.

12. A semiconductor device as claimed in claim 11, further comprising:
a second feed having a tree-structure for balancing a feed signal, the semiconductor element having a plurality of contacts that are electrically connected to the second feed.

13. A semiconductor device as claimed in claim 1, wherein
the electrode has a circular shape, and
the transistor element has a circular shape.

14. A semiconductor device as claimed in claim 13, wherein the threshold distance is not more than 300 microns.

15. A semiconductor device as claimed in claim 1, wherein
the electrode has a polygonal shape, and
the transistor element has a polygonal shape.

16. A semiconductor device as claimed in claim 15, wherein the threshold distance is not more than 300 microns.

17. A semiconductor device, comprising:
a semiconductor substrate;
an electrode disposed on an upper surface of the substrate; and
a set of transistor elements disposed on the upper surface of the substrate, the set including at least one transistor element, and each transistor element including at least one contact that is electrically connected to the electrode, wherein the set of transistor elements compactly surrounds the electrode with a threshold distance and a threshold angular value.

18. A semiconductor device as claimed in claim 17, wherein
the semiconductor substrate includes a via inner wall that defines a via, and
the via inner wall electrically connects the electrode with a second electrode disposed on a lower surface of the substrate.

19. A semiconductor device as claimed in claim 18, wherein the threshold angle is at least 180 degrees.

20. A semiconductor device as claimed in claim 19, wherein the threshold distance is no more than 300 microns.

21. A semiconductor device as claimed in claim 20, further comprising:
a feed having a tree-structure for balancing a feed signal, each semiconductor element having at least one contact that is electrically connected to the feed.

22. A semiconductor device as claimed in claim 21, further comprising:
a second feed having a tree-structure for balancing a feed signal, each semiconductor element having at least one contact that is electrically connected to the second feed.

23. A semiconductor device as claimed in claim 18, further comprising
an insulating layer disposed on the electrode;
a third electrode disposed on the insulating layer, each transistor element including at least one contact that is electrically connected to the second electrode; and
a metal connection that electrically connects the second electrode to a third electrode.

24. A semiconductor device as claimed in claim 23, wherein the threshold angle is at least 180 degrees.

25. A semiconductor device as claimed in claim 24, wherein the threshold distance is no more than 300 microns.

26. A semiconductor device as claimed in claim 25, further comprising:
a feed having a tree-structure for balancing a feed signal, each semiconductor element having at least one contact that is electrically connected to the feed.

27. A semiconductor device as claimed in claim 17, wherein a metal connection electrically connects the electrode to a second electrode.

28. A semiconductor device as claimed in claim 27, wherein the threshold angle is at least 180 degrees.

29. A semiconductor device as claimed in claim 28, wherein the threshold distance is no more than 300 microns.

30. A semiconductor device as claimed in claim 29, further comprising:
a feed having a tree-structure for balancing a feed signal, each semiconductor element having at least one contact that is electrically connected to the feed.

31. A semiconductor device as claimed in claim 30, further comprising:
a second feed having a tree-structure for balancing a feed signal, each semiconductor element having at least one contact that is electrically connected to the second feed.

32. A semiconductor device as claimed in claim 17, wherein the electrode has a circular shape.

33. A semiconductor device as claimed in claim 32, wherein the threshold angle is at least 180 degrees.

34. A semiconductor device as claimed in claim 33, wherein the threshold distance is no more than 300 microns.

35. A semiconductor device as claimed in claim 17, wherein the electrode has a polygonal shape.

36. A semiconductor device as claimed in claim 35, wherein the threshold angle is at least 180 degrees.

37. A semiconductor device as claimed in claim 36, wherein the threshold distance is no more than 300 microns.
